(19) United States
(12) Patent Application Publication
(10) Pub. No.: US 2022/0149058 A1
(43) Pub. Date: May 12, 2022

(54) SEMICONDUCTOR DEVICE

(71) Applicant: RENESAS ELECTRONICS CORPORATION, Tokyo (JP)

(72) Inventor: Yoshiyuki KAWASHIMA, Tokyo (JP)

(21) Appl. No.: 17/502,798

(22) Filed: Oct. 15, 2021

(30) Foreign Application Priority Data
Nov. 10, 2020 (JP) 2020-186941

(51) Int. Cl. H01L 27/11521; G11C 11/54; H01L 29/423; G11C 11/56

(52) U.S. Cl. CPC H01L 27/11521; G11C 11/5635; H01L 29/42324; G11C 11/54

(57) ABSTRACT

A plurality of non-volatile memory cells are used to realize synapses in a neural network circuit. A semiconductor device includes a memory cell array in which a plurality of non-volatile memory cells are arranged in an array. Each of the plurality of non-volatile memory cells has: a control gate electrode and a memory gate electrode that extend in a Y direction; a drain region; and a source region. Each of the plurality of drain regions is electrically connected to a bit line extending in a Y direction, and each of the plurality of source regions is electrically connected to a source line extending in an X direction.

### CROSS-REFERENCE TO RELATED APPLICATION

The present application claims priority from Japanese Patent Application No. 2020-186941 filed on Nov. 10, 2020, the content of which is hereby incorporated by reference into this application.

### BACKGROUND

The present invention relates to a semiconductor device, for example, a semiconductor device having a plurality of non-volatile memory cells.

In recent years, development of artificial intelligence has been remarkable, and various devices equipped with artificial intelligence have begun to spread. There are many methods known for artificial intelligence called machine learning, and one of them is a method using a neural network. The neural network is a network which represents, by a mathematical model of artificial neurons, nerve cells (neurons) and a neural circuit network composed of their connections in the human brain.

For example, Patent Document 1 (Japanese Unexamined Patent Application Publication No. 2018-195285) discloses that a non-volatile memory cell such as ReRAM (resistive random access memory) is used as a device for realizing a neural network circuit

Further, Patent Document 2 (Japanese Unexamined Patent Application Publication No. 2006-100531) discloses a flash memory or EEPROM (Electrically Erasable and Programmable Read Only Memory) as an example of a non-volatile memory cell, and discloses a MONOS (Metal Oxide Nitride Oxide Semiconductor) type memory cell.

### SUMMARY

In neurons, information is transmitted by using electrical signals as a means of transmission. At that time, ease of information transmission changes depending on a bond strength (strength of connection) of a synapse to be a bonding portion of the information transmission.

When a memory cell array like Patent Document 2, in which MONOS type memory cells are arranged in an array, is used to attempt to construct a neural network circuit, each memory cell needs to be weighted in order to configure synapses having bond strengths different in strength. For doing so, a bitwise write operation and erase operation are required.

FIG. 1 shows a plan view of a memory cell array MCA like Patent Document 2 in a conventional technique. FIG. 2 shows: each value of a write voltage, an erase voltage, and a read voltage of a selected non-volatile memory cell MC; and a value of a write voltage of a non-selected non-volatile memory cell MC.

As shown in FIG. 1, a control gate electrode CG to be a word line, a memory gate electrode MG formed on a charge storage layer, and a source line St extend in the same Y direction. Therefore, a plurality of memory cells MC connected to the same control gate electrode CG and memory gate electrode MG are connected also to the same source line SL.

Accordingly, the erase operation is simultaneously performed to the plurality of memory cells MC connected to the same control gate electrode CG and memory gate electrode MG, and is performed as a so-called word line batch erase. That is, since the bitwise erase operation cannot be performed, each memory cell MC cannot be weighted.

A main purpose of the present application is to realize the synapses in the neural network circuit by using the plurality non-volatile memory cells MC. Other problems and novel features will be apparent from descriptions of the present specification and the accompanying drawings.

According to one embodiment, a semiconductor device has a memory cell array in which a plurality of non-volatile memory cells are arranged in an array. Each of the plurality of non-volatile memory cells has a first gate dielectric film, a second gate dielectric film having a charge storage layer, a first gate electrode, a second gate electrode, a drain region, and a source region. Here, the plurality of first gate electrodes and the plurality of second gate electrodes each extend in a first direction in a plan view and are adjacent to each other in a second direction intersecting with the first direction in a plan view. Each of the plurality of drain regions is electrically connected to a bit line extending in the first direction, and each of the plurality of source regions is electrically connected to a source line extending in the second direction.

According to one embodiment, the synapses in the neural network circuit can be realized by using the plurality of non-volatile memory cells.

### BRIEF DESCRIPTION OF THE DRAWINGS

FIG. 1 is a plan view showing a memory cell array in a conventional technique.

FIG. 2 is a table showing a voltage value of each operation of a non-volatile memory cell.

FIG. 3 is a conceptual diagram showing a neural network.

FIG. 4 is a view showing a mathematical formula used in the neural network.

FIG. 5 is a plan view showing a layout of a semiconductor chip in a first embodiment.

FIG. 6 is a plan view showing a layout of a neural network circuit in the first embodiment.

FIG. 7 is a plan view showing a memory c array in the first embodiment.

FIG. 8 is a cross-sectional view showing a non-volatile memory cell in the first embodiment.

FIG. 9 is a table showing a voltage value of each operation of the non-volatile memory cell of the first embodiment.

FIG. 10 is a graph showing a change in current values of the non-volatile memory cell in the first embodiment.

FIG. 11 is a graph showing a change in current values of the non-volatile memory cell in the first embodiment.

### DETAILED DESCRIPTION

Hereinafter, an embodiment will be described in detail with reference to the drawings. Incidentally, through all the drawings for explaining the embodiment, members having the same function are denoted by the same reference numerals, and a repetitive description thereof will be omitted. Further, in the following embodiment, the description of the same or similar parts will not be repeated in principle except when being particularly necessary.

In addition, a X direction, a Y direction, and a Z direction described in the present application intersect with each other, and are orthogonal to each other. In the present application, the Z direction will be described as a vertical direction, a height direction, or a thickness direction of a certain structure. Further, the expression “plan view” used in the present application means that a surface configured in the X direction and the Y direction is viewed from the Z direction.

### First Embodiment

### About Neural Network

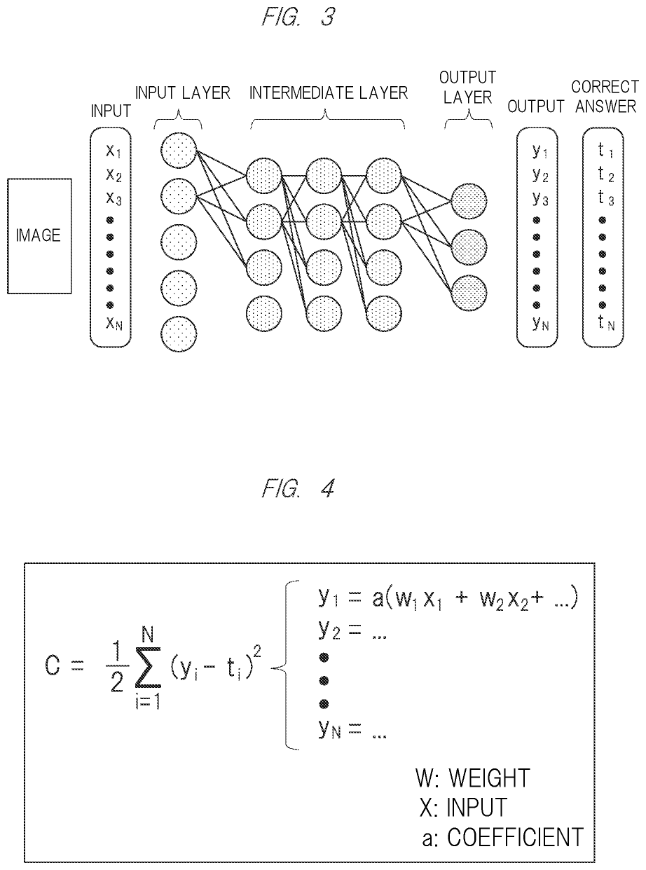

A concept of a neural network will be described below with reference to FIGS. 3 and 4. In a neural network, the ease of information transmission changes depending on a bond strength (strength of connection) of a synapse to be a bonding portion of the information transmission.

As shown in FIG. 3, the neural network is configured by an input layer, an intermediate layer, and an output layer, and the synaptic bond strength is expressed as “weight w” existing among the respective layers.

In order to observe an image of FIG. 3, a size of the input layer can be caused to correspond to the number of pixels, and an “input x” can be caused to correspond to an electric signal. Further, it is known that calculation for deriving an “output y” from the “input x” and the “weight w” can be expressed by a mathematical formula shown in FIG. 4.

When the “input x” is inputted as data to the input layer from the image, a product of the “input x” and the “weight w” is calculated as the “output y” in the output layer. As types of “input x” and “weight w” are many, their products are added and the predetermined “output y” becomes more detailed information.

In addition, in the intermediate layer, a product of a previous stage (for example, the product of the “input x” and the “weight w” from the input layer) is further multiplied by the “weight w”, thereby being weighted. As the number of intermediate layers increases, weighting is performed each time, so that the “output y” becomes more detailed information.

For example, when the image is a monkey, an “output y1” is related to information on mammals, an “output y2” is related to information on a face's shape, an “output y3” is related to information on a hand's shape, and so on, so that the respective pieces of information are related to the image and can get closer to a correct answer.

In addition, the correct answer of the image is converted into data as a “correct answer t” in advance. An “error C” can be obtained by using a difference between the “output y” and the “correct answer t”, and it can be said that as a value of the “error C” becomes small, the accurate image data can be obtained. Therefore, as the respective types of “input x” and “weight w” become many and the types of “output y” become many the more accurate image data can be obtained.

For example, when a neural network circuit C1 described below is used, it is possible to cause the “input x” to correspond to a signal of a control gate electrode CG, cause the “weight w” to correspond to a threshold voltage Vth of the non-volatile memory cell MC, and cause the “output y” to correspond to a value of a current flowing through the non-volatile memory cell MC (a value of a current flowing between a drain region and a source region).

### Configurations of Semiconductor Chip CHP and Neural Network Circuit C1

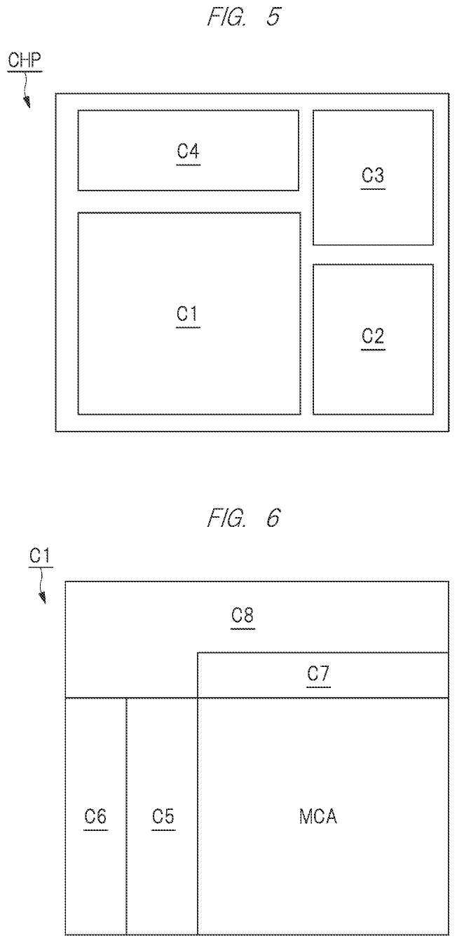

FIG. 5 is a plan view showing a layout of a semiconductor chip CHP which is a semiconductor device according to the first embodiment. A semiconductor chip CHP includes, for example, a neural network circuit C1, a ROM (Read Only Memory) circuit C2, a RAM (Random Access Memory) circuit C3, and a logic circuit C4. Although not shown here, the semiconductor chip CHP may be further provided with an input/output circuit (I/O circuit) an analog circuit, and the like.

The neural network circuit C1 is an area in which an EEPROM capable of electrically rewriting stored information is formed as a semiconductor element.

The ROM circuit C2 is a circuit, which does not write the stored information and only reads the stored information. In the ROM circuit C2, an EEPROM having substantially the same structure as that in the neural network circuit C1 can be applied as a semiconductor element.

The logic circuit C3 is an area in which a low withstand voltage transistor driven at a low voltage of about 1.5 V, having a low withstand voltage, and operating quickly is formed as a semiconductor element. For example, a CPU (Central Processing Unit) is configured by the semiconductor element of the logic circuit C3.

The RAM circuit C4 is, for example, an SRAM (Static RAM), and is an area in which a low withstand voltage transistor having a structure substantially similar to that of the logic circuit C3 is formed as a semiconductor element.

FIG. 6 is a plan view showing a layout of the neural network circuit C1 shown in FIG. 5.

The neural network circuit C1 includes, for example, a memory cell array MCA, a word line driver C5, an input/output unit C6, a bit line selector C7, and an arithmetic circuit C8.

The word line driver C5 supplies, to the word line diver C5, a voltage supplied from outside the neural network circuit via the input/output unit C6.

The word line driver C5 is provided with a booster circuit or the like, and the booster circuit generates a voltage required for a write operation, an erase operation, or a read operation. In each operation, an appropriate voltage among the generated voltages is supplied to a plurality of control gate electrodes CG, a plurality of memory gate electrodes MG, and a plurality of source lines SL.

The bit line selector C7 includes a sense amplifier, and can read stored information of the selected non-volatile memory cell MC via the bit line BL. Further, the bit line selector C7 can select the non-volatile memory cell MC to be written or erased of the stored information via the bit line BL. The arithmetic circuit C8 can perform calculation of the stored information.

### Configuration of Memory Cell Array MCA (Plurality of Non-Volatile Memory Cells MC)

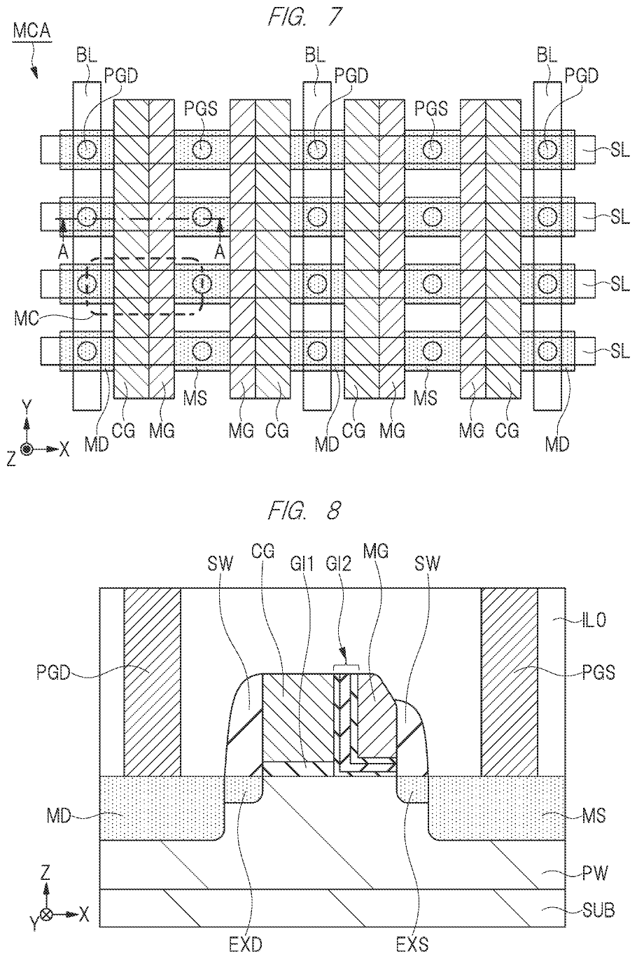

FIG. 7 is a plan view showing the memory cell array MCA in the first embodiment. FIG. 8 is a cross-sectional view of the non-volatile memory cell MC taken along line A-A shown in FIG. 7.

The non-volatile memory cell MC in the first embodiment is EEPROM and is a MONOS type memory cell. A memory cell array MCA is configured by arranging a plurality of non-volatile memory cells MC in an array.

As shown in FIG. 8, the plurality of non-volatile memory cells MC each have: a gate dielectric film GI1; a gate dielectric film GI2 having a charge storage layer; a control gate electrode CG; a memory gate electrode MG; an extension region EXD and a diffusion region MD that are drain regions; and an extension region EXS and a diffusion region MS that are source regions.

Incidentally, in the first embodiment, a transistor having the gate dielectric film GI1 and the control gate electrode CG may be referred to as a selection transistor, and a transistor having the gate dielectric film GI2 and the memory gate electrode MG may be referred to as a memory transistor.

A semiconductor substrate SUB is made of, for example, p-type silicon. A p-type well region PW is formed on the semiconductor substrate SUB.

The gate dielectric film GI1 made of, for example, silicon oxide is formed on the semiconductor substrate SUB. The control gate electrode CG made of, for example, polycrystalline silicon is formed on the gate dielectric film GI1.

Further, the gate dielectric film GI2 is formed on the semiconductor substrate SUB and on a side surface of the control gate electrode CG. The memory gate electrode MG made of, for example, polycrystalline silicon and processed into a sidewall shape is formed on the gate dielectric film GI1. The control gate electrode CG and the memory gate electrode MG are adjacent to each other in an X direction via the gate dielectric film GI2.

The gate dielectric film GI2 is composed of, for example, a laminated film, and the laminated film is composed of a silicon oxide film, a charge storage layer, and a silicon oxide film. The charge storage layer is a film provided for storing data of the memory cell MC, is a dielectric film having a trap level capable of retaining (holding) charges, and is made of for example, silicon nitride.

A sidewall spacer SW made of a dielectric film such as a silicon nitride film is formed on each side surface of the control gate electrode CG and the memory gate electrode MG. An n-type extension region EXD and an n-type diffusion region MD are formed in the semiconductor substrate SUE on a side of the control gate electrode CG, and an n-type extension region EXS and an n-type diffusion region MS are formed in the semiconductor substrate SUB on a side of the memory gate electrode MG. Each of the diffusion region MD and the diffusion region MS has a higher impurity concentration than each of the extension region EXD and the extension region EXS.

An interlayer dielectric film IL0 made of, for example, silicon oxide is formed on the semiconductor substrate SUB so as to cover such a non-volatile memory cell MC. A plurality of contact holes are formed in the interlayer dielectric film IL0, and a plurality of plugs are formed in the interlayer dielectric film IL0 by embedding, for example, a conductive film mainly composed of tungsten inside the contact holes. Among such a plurality of plugs, a plug PGD is electrically connected to the diffusion region MD, and a plug PCS is electrically connected to the diffusion region MS.

As shown in FIG. 7, the diffusion region MD is electrically connected to a bit line EL via the plug PGD, and the diffusion region MS is electrically connected to a source line SL via the plug PGS. The bit line BL is, for example, a wiring of a first layer, and the source line SL is, for example, a wiring of a second layer. Each wiring is made of a conductive film mainly composed of an aluminum film or a copper film.

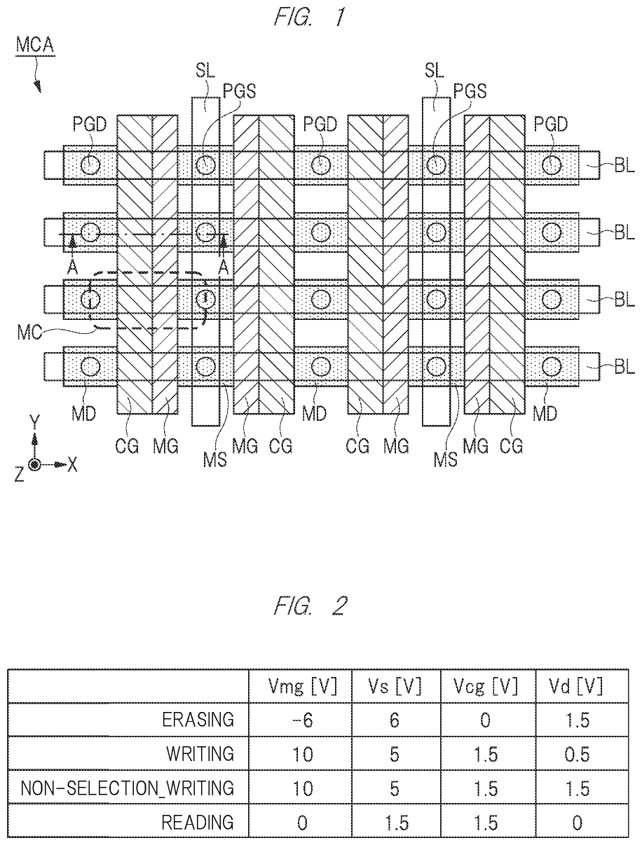

The memory cell array MCA includes a plurality of non-volatile memory cells MC, but the plurality of control gate electrodes CG and the plurality of memory gate electrodes MG each extend in a Y direction. Then, in the conventional technique of FIG. 1, the source line SL extends in the Y direction and the bit line BL extends in the X direction, but in the first embodiment of FIG. 7, the source line EL extends in the X direction and the bit line BL extends in the Y direction.

Consequently, in the first embodiment, the write operation and the erase operation can be performed in units of bit. Each threshold voltage Vth of the plurality of non-volatile memory cells MC (plurality of memory transistors) can be changed depending on a charge amount stored in the charge storage layer. Therefore, the write operation and the erase operation for changing the threshold voltages Vth of the plurality of non-volatile memory cells MC are individually performed to the plurality of non-volatile memory cells MC.

### Each Operation of Non-volatile Memory MC

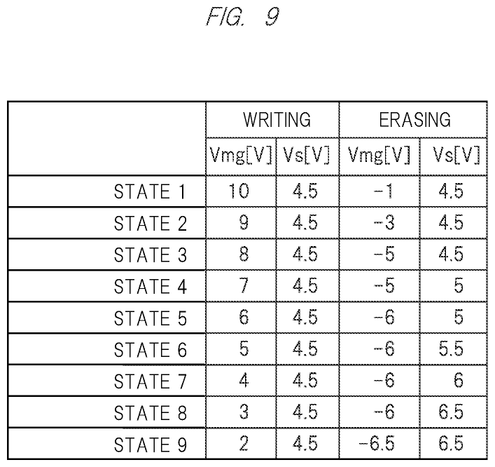

The respective voltage values of the write operation, the erase operation, and the read operation to the non-volatile memory cell MC are almost the same as those shown in FIG. 2, but, as shown in FIG. 9 described later, voltages Vmg and Vs of the write operation and the erase operation are different from those of FIG. 2.

The respective voltages shown in FIGS. 2 and 9 are the voltage Vmg applied to the memory gate electrode MG, the voltage Vs applied to the diffusion region MS which is the source region, a voltage Vcg applied to the control gate electrode CG, and a voltage Vd applied to the diffusion region MD which is the drain region.

Incidentally, the voltage value is an example, is not limited to these, and can be variously changed as needed. Further, in the first embodiment, an injection of electrons into the charge storage layer in the gate dielectric film GF2 is defined as “write”, and an injection of holes (positive holes) into the charge storage layer in the gate dielectric film GF2 is defined as “erase”.

The write operation can use a wri method called an SSI (Source Side Injection) method in which writing is performed by a hot electron injection. That is, the write operation is performed by accelerating electrons from the drain region (diffusion region MD, extension region EXD) toward the source region (diffusion region MS, extension region EXS) and injecting the accelerated electrons into a charge storage layer CSL. The injected electrons are trapped at a trap level (s) in the charge storage layer and, as a result, the threshold voltage Vth of the non-volatile memory cell MC (memory transistor) rises. That is, the non-volatile memory cell MC becomes a write state.

The erase operation can use an erasing method called a BTBT (Band-To-Band Tunneling) method in which erasing is performed by a hot hole injection. That in the source region, holes are generated by a BTBT phenomenon, and are injected into the charge storage layer by acceleration due to an electric field. Consequently, the threshold voltage Vth of the non-volatile memory cell MC (memory transistor) decreases. That is, the non-volatile memory cell MC becomes an erase state.

In the read operation, the voltage Vmg is set to a value between the threshold voltag Vth of the memory transistor in the write state and a threshold voltage of the memory transistor in the erase state. Therefore, by reading a value of a current flowing between the drain region and the source region, it is possible to determine whether the non-volatile memory cell MC is in the write state or the erase state.

As described above, in the first embodiment, the values shown in FIG. 9 are used for the voltage Vmg and the voltage Vs in the write operation and the erase operation. By using such values, a voltage difference between the memory gate electrode MG and the source region can be made different between the write operation and the erase operation. Consequently, as shown in FIG. 9, the plurality of non-volatile memory cells MC each different in threshold voltage Vth can be prepared. Here, nine non-volatile memory cells MC each different in threshold voltage Vth are shown as States 1 to 9.

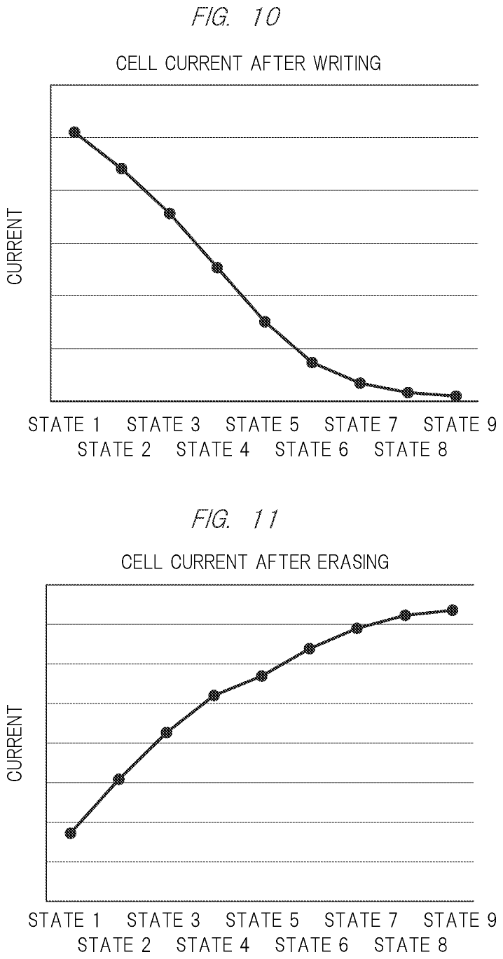

FIG. 10 is a graph showing a change in current values of the non-volatile memory cell MC after the writing, and FIG. 11 is a graph showing a change in current values of the non-volatile memory cell MC after the erasing.

Since the respective threshold voltages Vth of the plurality of non-volatile memory cells MC are different as shown by States 1 to 9, the values of the currents flowing between the drain region and the source region in the read operations of the plurality of non-volatile memory cells MC are different for each of the plurality of non--volatile memory cells MC. That is, the threshold voltages Vth of the plurality of non-volatile memory cells MC are set to multiple stages, and the values of the respective currents flowing through the plurality of non-volatile memory cells MC are also set to multiple stages.

### Main Effects of First Embodiment

According to the first embodiment, the “input x”, the “weight w” and the “output y” described in FIGS. 3 and 4 can respectively be caused to correspond to the signal of the control gate electrode CG, the threshold value Vth of the non-volatile memory cell MC, and the value of the current flowing through the non-volatile memory cell MC (the value of the current flowing between the drain region and the source region).

First, in the plurality of non-volatile memory cells MC, since each extension direction of the source line SL and the bit line BL is designed to be different from those in the conventional technique, the write operation and the erase operation can be performed in units of bit.

Therefore, as shown in States 1 to 9 of FIG. 9, the voltage difference between the memory gate electrode MG and the source region can be made different in the write operation and the erase operation, and the plurality of non-volatile memory cells MC each different in threshold voltage Vth can be prepared.

Consequently, as shown in FIGS. 10 and 11, in the read operations of the plurality of non-volatile memory cells MC, the value of the current flowing between the drain region and the source region can be made different for each of the plurality of non-volatile memory cells MC. Then, use of the values of the different currents makes it possible to realize the bond strength of the synapse of the neural network circuit C1.

In this way, using the plurality of non-volatile memory cells MC in the first embodiment makes it possible to realize the synapse in the neural network circuit C1.

Further, in the first embodiment, as the non-volatile memory cell MC, the MONOS type memory cell in which the dielectric film having the trap level serves as the charge storage layer has been applied. The MONOS type memory cell has fewer defective bits and can maintain longer rewrite endurance than other memory cells such as resistance change memory (ReRAM), magnetoresistive memory (MRAM) and ferroelectric memory (FeRAM). Therefore, the semiconductor device according to the first embodiment can ensure reliability for a long period of time.

In addition, as shown in FIGS. 10 and 11, since a stable current transition can be obtained in the MONOS type non-volatile memory cell MC, the “weight w” is easily given with stability. Therefore, the neural network circuit C1 can be easily realized as compared with other memory cells.

As described above, although the present invention has been specifically explained based on the above-described embodiment, the present invention is not limited to the above-described embodiment. and can be variously modified without departing from the gist thereof.

What is claimed is:

1. A semiconductor device having a plurality of non-volatile memory cells, each of the plurality of non-volatile memory cells comprising:
a first gate dielectric film formed on a semiconductor substrate;
a second gate dielectric film formed on the semiconductor substrate and having a charge storage layer;
a first gate electrode formed on the first gate dielectric film;
a second gate electrode formed on the second gate dielectric film;
a drain region formed in the semiconductor substrate on a side of the first gate electrode; and
a source region formed in the semiconductor substrate on a side of the second gate electrode,
wherein the plurality of first gate electrodes and the plurality of second gate electrodes each extend in a first direction in a plan view and are adjacent to each other in a second direction intersecting with the first direction in a plan view,
wherein each of the plurality of drain regions is electrically connected to a bit line extending in the first direction, and
wherein each of the plurality of source regions is electrically connected to a source line extending in the second direction.

2. The semiconductor device according to claim
wherein a threshold voltage of each of the plurality of non-volatile memory cells can be changed by a charge amount stored in the charge storage layer, and
wherein a write operation and an erase operation for changing the threshold voltage of each of the plurality of non-volatile memory cells are individually performed to the plurality of non-volatile memory cells.

3. The semiconductor device according to claim 2,
wherein by making a voltage difference between the second gate electrode and the source region different in the write operation and the erase operation, the respective threshold voltages of the plurality of non-volatile memory cells have different values.

4. The semiconductor device according to claim 3,
wherein a value of a current flowing between the drain region and the source region is different for each of the plurality of non-volatile memory cells in the read operations of the plurality of non-volatile memory cells.

5. The semiconductor device according to claim 4,
wherein the plurality of non-volatile memory cells configure a part of a neural network circuit, and
wherein a bond strength of a synapse is realized by the value of the different current.

6. The semiconductor device according to claim 5,
wherein the charge storage layer is made of silicon nitride,
wherein electrons are injected from the drain region into the charge storage layer in the write operation, and
wherein holes are injected from the source region into the charge storage layer in the erase operation.
